(19) United States
(12) Patent Application Publication
(10) Pub. No.: US 2026/0344504 A1
(43) Pub. Date: Oct. 29, 2026

(54) Semiconductor Device and Method of Forming Barrier to Impede Underfill Material from Reaching Sensitive Areas

(71) Applicant: STATS ChipPAC Management Pte. Ltd., Singapore (SG)

(72) Inventors: YoonSeok Cho, Gyeonggi-do (KR); KyungHoon Lee, Gyeonggi-do (KR); NamHyun Lee, Incheon (KR)

(73) Assignee: STATS ChipPAC Management Pte. Ltd., Singapore (SG)

(21) Appl. No.: 19/187,738

(22) Filed: Apr. 23, 2025

(51) Int. Cl. H10W 76/40; G02B 6/13; H10W 74/10; H10W 74/15; H10W 90/00

(52) U.S. Cl. CPC H10W 76/40; G02B 6/13; H10W 74/131; H10W 74/15; H10W 90/724; H10W 90/734

(57) ABSTRACT

A semiconductor device has an electrical component including a waveguide formed on the electrical component. A barrier is disposed proximate to the waveguide or other optical region. The barrier can be a trench, dam, or post, or combination thereof. For example, there can be a trench and a dam, or a trench and a post, or a trench, dam, and post, or combination thereof. The electrical component is disposed over an interconnect substrate. A conductive pillar is formed between the interconnect substrate and the electrical component. An underfill material is deposited between the electrical component and interconnect substrate. The barrier impedes or blocks the underfill material from reaching the waveguide. The trench can be a linear path, U-shaped or with side wings. The dam extends between the electrical component and interconnect structure. A plurality of posts can be disposed between the electrical component and interconnect structure.

### FIELD OF THE INVENTION

The present invention relates in general to semiconductor devices and, more particularly, to a semiconductor device and method of forming a barrier to impede underfill material from reaching a sensitive area of co-packaged optics (CPO).

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Some semiconductor die have a waveguide to guide electromagnetic waves, such as radio waves, microwaves, or light waves, from one location to another. For example, a photonic integrated circuit (PIC) uses an optically sensitive area to convert optical data to electrical signals. The waveguide directs light from an external source to the optically sensitive area of the semiconductor die. The demand for high transmittance can be associated with artificial intelligence (AI) and large data center operations. One advantage of PICs is enablement, extending, and increasing data transmission. An application for PICs is integration with ASIC, known as co-packaged optics (CPO), to achieve the goal higher data speed.

In such CPO applications, the semiconductor device also uses various blocks or die to process the electrical signal received from the external light source. These die are often sealed with underfill material. However, underfill material is difficult to control in terms of flow rate and direction, i.e., the underfill bleeding effect. It is important to avoid allowing the underfill material to reach the waveguide, as that would likely cause defects by blocking the optical transmission and reception.

### BRIEF DESCRIPTION OF THE DRAWINGS

FIGS. 1a-1f illustrate a semiconductor wafer with a plurality of semiconductor die separated by a saw street;

FIGS. 2a-2g illustrate a process of forming an interconnect substrate with conductive pillars;

FIGS. 3a-3g illustrate a process of forming a barrier to impede underfill material from reaching a sensitive area of a PIC;

FIGS. 4a-4e illustrate a process of integrating the PIC and interconnect substrate and applying underfill material between the devices as the barrier impedes the underfill material from reaching a sensitive area of a PIC;

FIGS. 5a-5d illustrate another barrier impeding the underfill material from reaching a sensitive area of the PIC;

FIGS. 6a-6d illustrate yet another barrier impeding the underfill material from reaching the sensitive area;

FIGS. 7a-7b illustrate yet another barrier impeding the underfill material from reaching the sensitive area;

FIGS. 8a-8b illustrate yet another barrier impeding the underfill material from reaching the sensitive area;

FIGS. 9a-9b illustrate yet another barrier impeding the underfill material from reaching the sensitive area; and

FIGS. 10a-10f illustrate yet another barrier impeding the underfill material from reaching the sensitive area; and

FIG. 11 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention’s objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

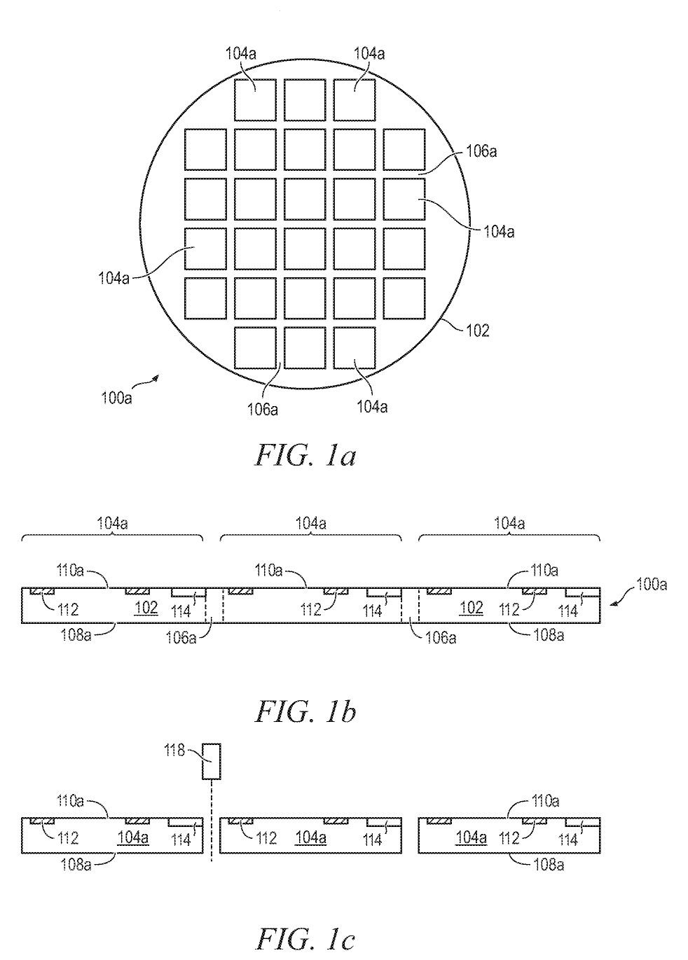

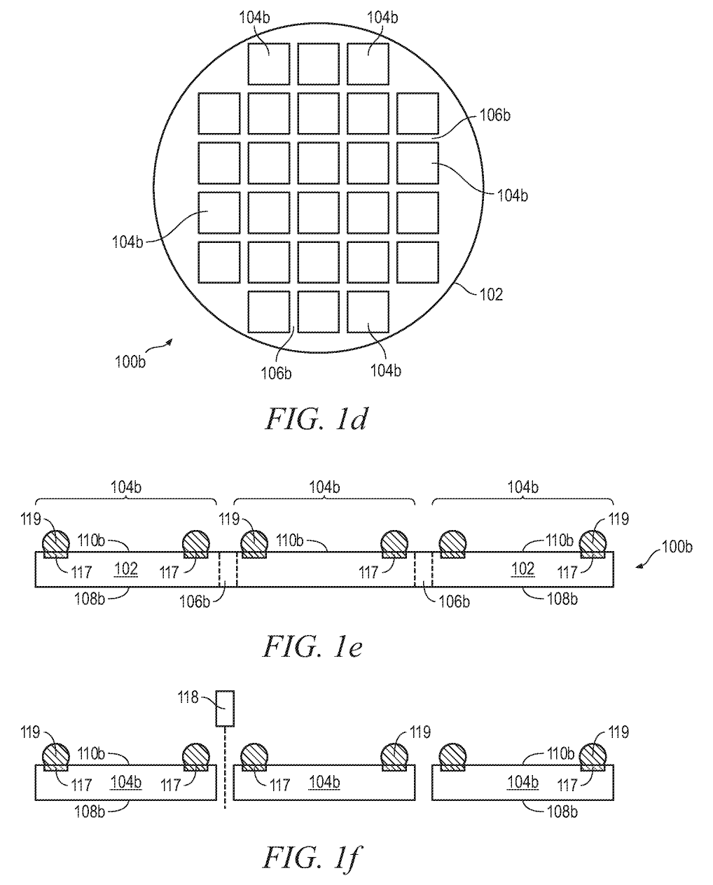

FIG. 1a shows a semiconductor wafer 100a with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104a is formed on wafer 100a separated by a non-active, inter-die wafer area or saw street 106a. Saw street 106a provides cutting areas to singulate semiconductor wafer 100a into individual semiconductor die 104a. In one embodiment, semiconductor wafer 100a is circular with a diameter of 100-450 millimeters (mm). Semiconductor wafer 100a can be rectangular or any other geometric shape.

FIG. 1b shows a cross-sectional view of a portion of semiconductor wafer 100a. Each semiconductor die 104a has a back or non-active surface 108a and an active layer 110a containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active layer 110 to implement analog circuits or digital circuits, such as digital signal processor (DSP), application specific integrated circuits (ASIC), memory, or other signal processing circuit. Semiconductor die 104a may also contain IPDs, such as inductors, capacitors, and resistors, for RF signal processing.

An electrically conductive layer 112 is formed over or within active layer 110a using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads or redistribution layer (RDL) electrically connected to the circuits in active layer 110a. Portions of conductive layer 112 can be electrically common or electrically isolated depending on the design and function of semiconductor die 104a within semiconductor wafer 100a and other electrical components.

Each semiconductor die 104a further contains waveguide 114. Waveguide 114 is a physical structure used to guide electromagnetic waves, such as radio waves, microwaves or light waves, from one location to another. The basic function of a waveguide is to provide a path for electromagnetic waves while minimizing their loss and maintaining their integrity. In one embodiment, waveguide 114 receives light and directs the light to the intended location. The intended location may be an optical coupler disposed in core area 102 and designated to receive the light and convert the light to an electrical signal.

In FIG. 1c, semiconductor wafer 100a is singulated through saw street 106a using a saw blade or laser cutting tool 118 into individual semiconductor die 104a. The individual semiconductor die 104a can be inspected and electrically tested for identification of known good die or unit (KGD/KGU) post singulation.

In another case, FIG. 1d shows a semiconductor wafer 100b, made similar to semiconductor wafer 100a. A plurality of semiconductor die or components 104b is formed on wafer 100b separated by a non-active, inter-die wafer area or saw street 106b. Saw street 106b provides cutting areas to singulate semiconductor wafer 100b into individual semiconductor die 104b. In one embodiment, semiconductor wafer 100b is circular with a diameter of 100-450 mm. Semiconductor wafer 100b can be rectangular or any other geometric shape.

FIG. 1e shows a cross-sectional view of a portion of semiconductor wafer 100b. Each semiconductor die 104b has a back or non-active surface 108b and an active layer 110b containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active layer 110 to implement analog circuits or digital circuits, such as DSP, ASIC, memory, or other signal processing circuit. Semiconductor die 104b may also contain IPDs, such as inductors, capacitors, and resistors, for RF signal processing. Semiconductor die 104b may have a different electrical function as semiconductor die 104a.

An electrically conductive layer 117 is formed over or within active layer 110b using PVD, CVD, electrolytic plating, electroless plating process, or other suitable metal deposition process. Conductive layer 117 can be one or more layers of Al, Cu, Sn, Ni, Au, Ag, or other suitable electrically conductive material. Conductive layer 117 operates as contact pads or RDL electrically connected to the circuits in active layer 110b.

An electrically conductive bump material is deposited over conductive layer 120 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 117 using a suitable attachment or bonding process. In one embodiment, the bump material is reflowed by heating the material above its melting point to form balls or bumps 119. In one embodiment, bump 119 is formed over an under bump metallization (UBM) having a wetting layer, barrier layer, and adhesive layer. Bump 119 can also be compression bonded or thermocompression bonded to conductive layer 117. Bump 119 represents one type of interconnect structure that can be formed over conductive layer 117. The interconnect structure can also use bond wires, conductive paste, stud bump, micro bump, or other electrical interconnect.

In FIG. 1f, semiconductor wafer 100b is singulated through saw street 106b using a saw blade or laser cutting tool 118 into individual semiconductor die 104b. The individual semiconductor die 104b can be inspected and electrically tested for identification of KGD/KGU post singulation.

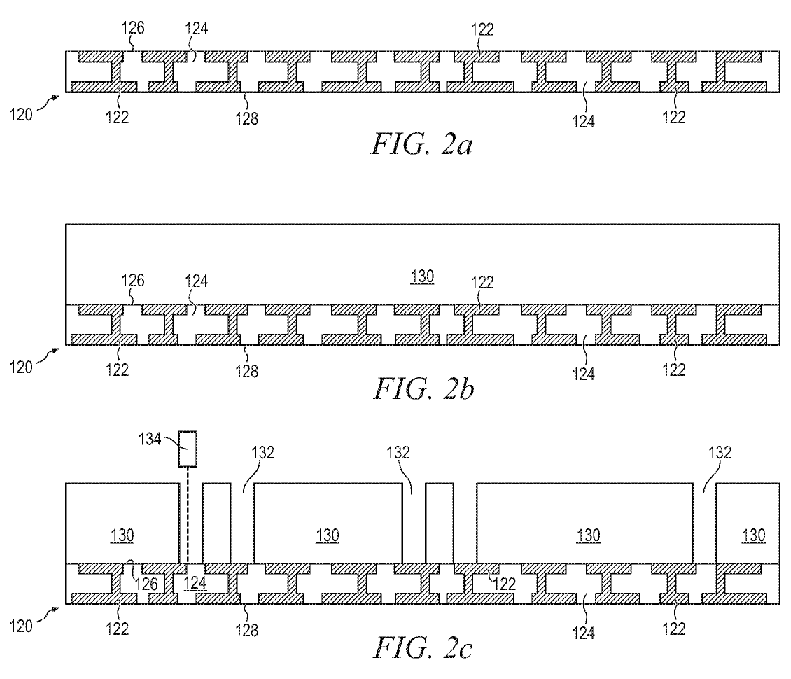

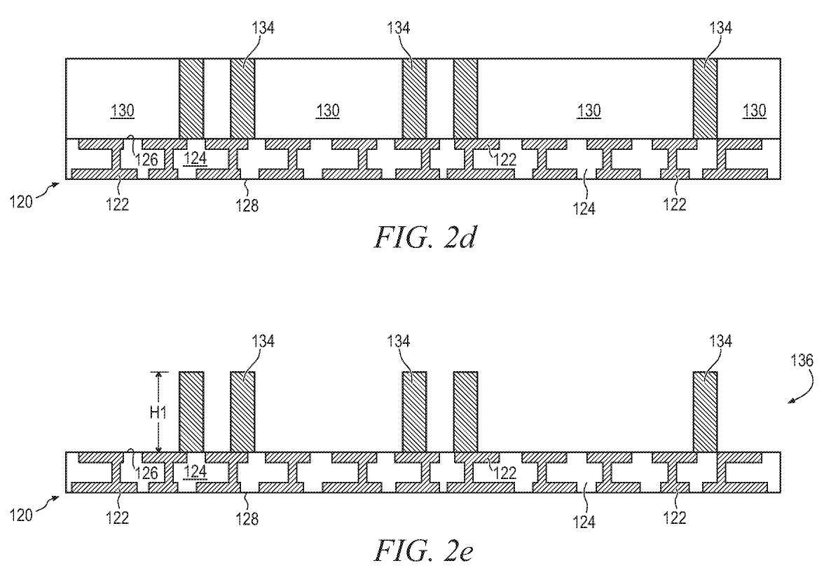

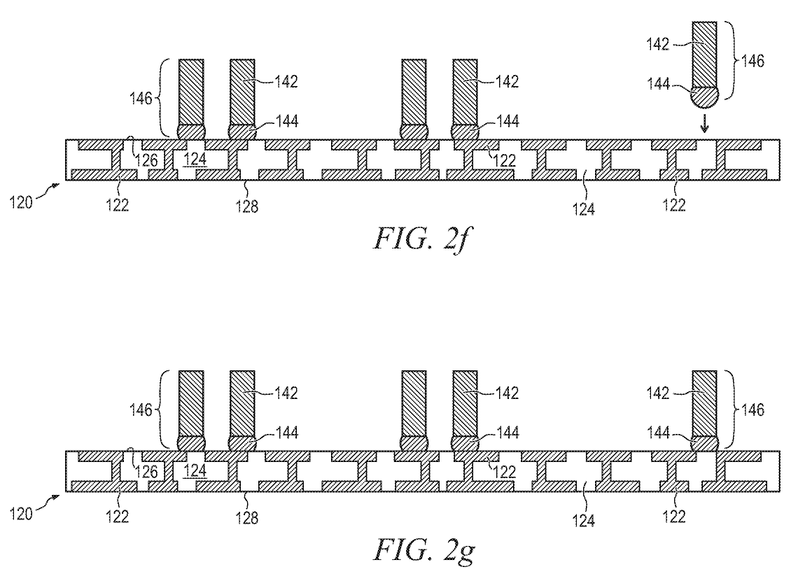

FIGS. 2a-2g illustrate a process of forming an interconnect substrate with conductive pillars. FIG. 2a shows a cross-sectional view of interconnect substrate 120 including one or more conductive layers 122 and one or more insulating layers 124. Conductive layers 122 can be one or more layers of Al, Cu, Sn, Ni, Au, Ag, or other suitable electrically conductive material. Conductive layers 122 can be formed using PVD, CVD, electrolytic plating, electroless plating process, or other suitable metal deposition process. Conductive layers 122 provide horizontal electrical interconnect (such as RDL), and vertical electrical interconnect. Portions of conductive layers 122 can be electrically common or electrically isolated depending on the design and function of electrical components attached thereto. Insulating layers 124 contain one or more layers of SiO2, Si3N4, SiON, Ta2O5, Al2O3, solder resist, polyimide, BCB, PBO, and other material having similar insulating and structural properties. Insulating layers 124 can be formed using PVD, CVD, printing, lamination, spin coating, spray coating, sintering or thermal oxidation. Insulating layers 124 provide isolation between conductive layers 122. There can be multiple conductive layers like 122 separated by insulating layers 124. Interconnect structure 120 has a major surface 126 and a major surface 128 opposite surface 126.

In FIG. 2b, a photoresist layer 130 is formed over surface 126. In FIG. 2c, a portion of photoresist layer 130 is removed by laser direct ablation (LDA) using laser 133 to form openings 132 defining the locations to form conductive pillars. In FIG. 2d, an electrically conductive material is deposited in openings 132 using PVD, CVD, electrolytic plating, electroless plating process, or other suitable metal deposition process to form conductive pillars 134. Conductive pillars 134 can be one or more layers of Al, Cu, Sn, Ni, Au, Ag, or other suitable electrically conductive material. In FIG. 2e, the remaining portion of photoresist layer 130 is removed, leaving conductive pillars 134 formed over substrate 120. Conductive pillars 134 have height H1 of 60.0-120.0 mm, or preferably 85.0 mm, and are electrically and mechanically connected to conductive layer 122 of interconnect substrate 120, as assembly 136.

In another embodiment, conductive pillars 146 have a conductive post 142 and conductive solder ball 144. Conductive pillars 146 are mounted to interconnect substrate 120 using a pick and place operation, as shown in FIG. 2f. Conductive solder balls 144 are reflowed to electrically and mechanically connect conductive pillars 146 to conductive layer 122 of interconnect substrate 120. FIG. 2g shows conductive pillars 146 electrically and mechanically connected to conductive layer 122 of interconnect substrate 120, as assembly 148. Conductive pillars 146 have a similar height as conductive pillars 134.

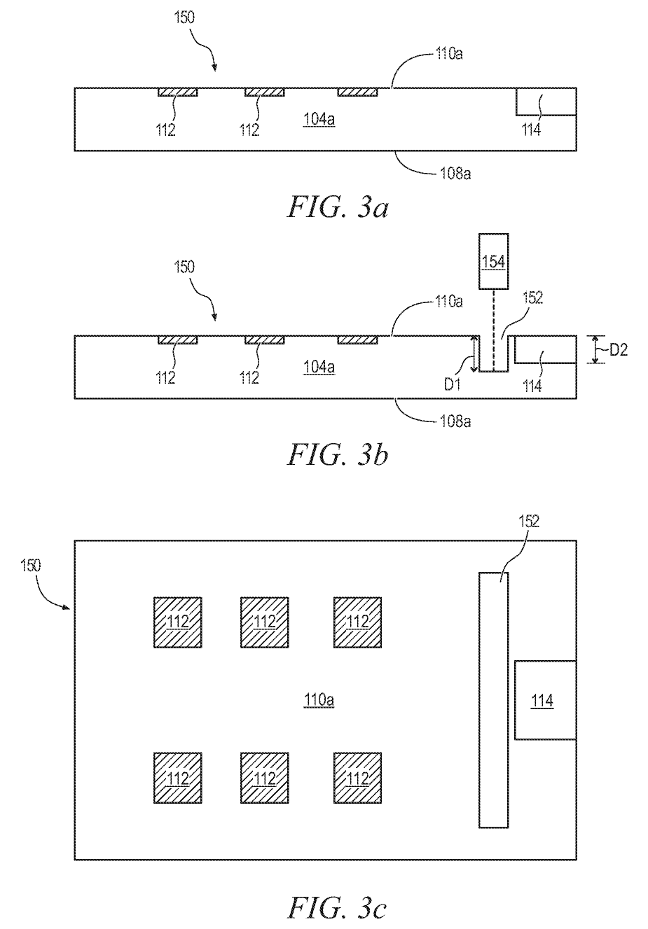

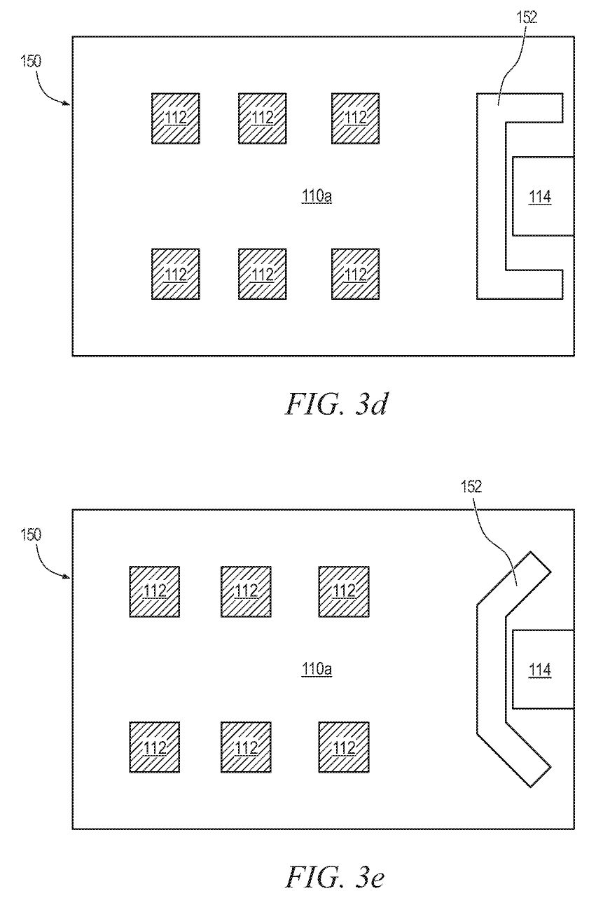

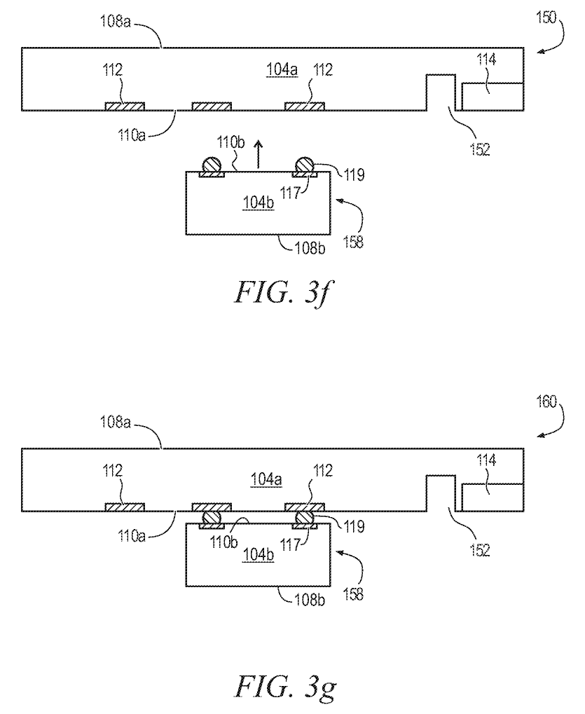

FIG. 3a shows electrical component 150 made similar to semiconductor die 104a from FIG. 1c, as a PIC with waveguide 114. Alternatively, electrical component 150 can include other semiconductor die, semiconductor packages, surface mount devices, discrete electrical devices, or IPDs.

In FIG. 3b, a trench or channel 152 is formed in a surface of electrical component 150 proximate to waveguide 114 using laser 154. In one embodiment, trench 152 has a depth D1 of at least 10.0 mm, and waveguide 114 has a depth D2 of less than 30.0 mm. Trench 152 can be deeper than waveguide 114. FIG. 3c shows a top view of trench or channel 152 formed in a surface of electrical component 150 in a linear path. FIG. 3d shows a top view of another embodiment of trench or channel 152 formed in a surface of electrical component 150 in the U-shape. FIG. 3e shows a top view of another embodiment of trench or channel 152 formed in a surface of electrical component 150 with side wings. Trench 152 covers an area of electrical component 150 as necessary to impede or block subsequently applied underfill material from reaching waveguide 114.

In FIG. 3f, electrical component 158 is positioned over electrical component 150 using a pick and place operation. Electrical component 158 can be similar to semiconductor die 104b from FIG. 1f with bumps 119 oriented toward the surface of electrical component 150 containing trench 152. In one embodiment, electrical component 158 is a transimpedance amplifier. Alternatively, electrical component 158 can include other semiconductor die, semiconductor packages, surface mount devices, discrete electrical devices, or IPDs. FIG. 3g shows electrical component 158 mounted to electrical component 150 with bumps 119 mechanically and electrically connected to conductive layer 112. Electrical component 158 bonded to electrical component 150 constitutes electrical assembly 160.

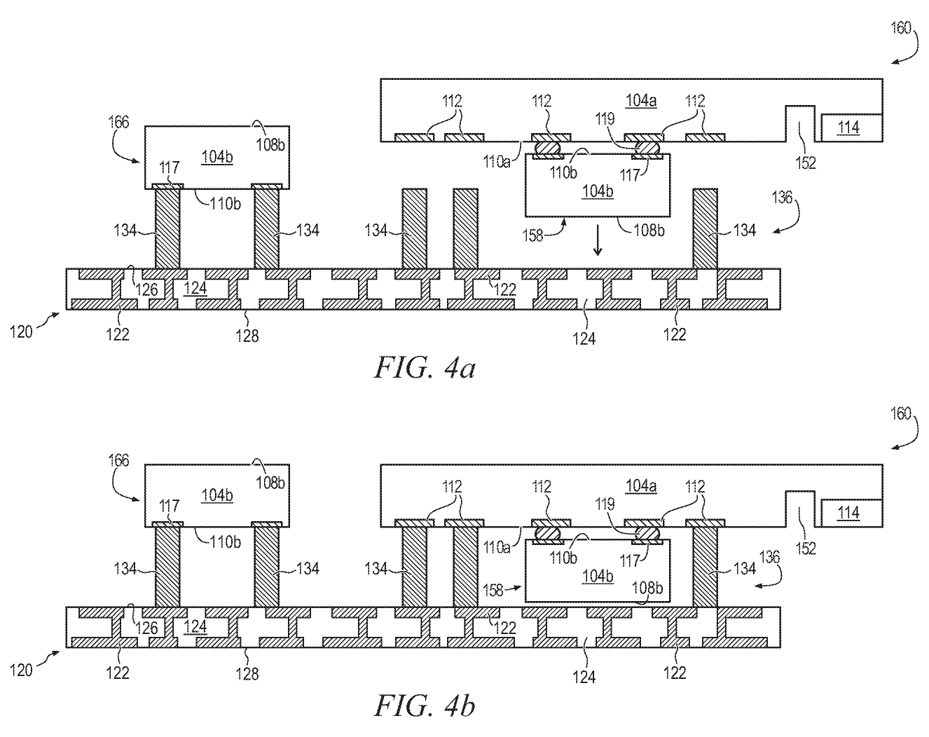

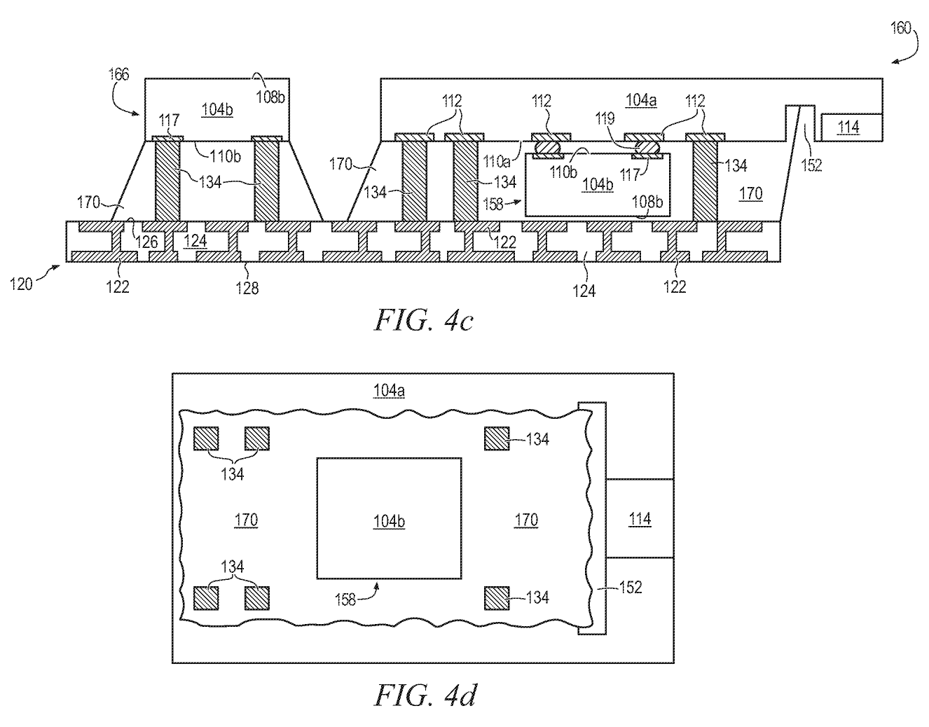

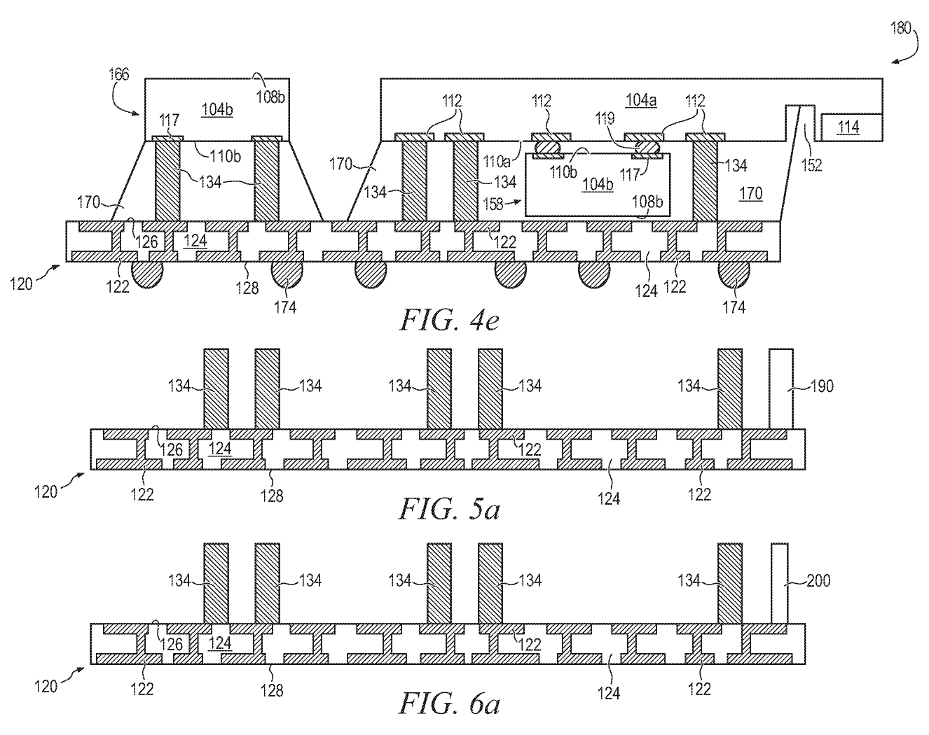

In FIG. 4a, electrical assembly 160 is positioned over interconnect substrate 120 using a pick and place operation with electrical component 158 disposed between conductive pillars 134 of assembly 136. Assembly 148 could have been used as well. Similarly, electrical component 166 is positioned over interconnect substrate 120 using a pick and place operation. Electrical component 166 can be similar to semiconductor die 104b from FIG. 1f, albeit without bumps 119, but instead with conductive layer 117 oriented toward surface 126. In one embodiment, electrical component 166 is an electronic integrated circuit. Alternatively, electrical component 166 can include other semiconductor die, semiconductor packages, surface mount devices, discrete electrical devices, or IPDs. FIG. 4b shows electrical assembly 160 and electrical component 166 mounted to interconnect substrate 120 with conductive pillars 134 mechanically and electrically connected to conductive layer 112 of electrical component 150 and to conductive layer 117 of electrical component 166.

In FIG. 4c, an underfill material 170, such as epoxy resin, is deposited between electrical assembly 160 and interconnect substrate 120 and further between electrical component 166 and interconnect substrate 120. The dispensing of underfill material 170 can be difficult to control. Any excess underfill material 170 flows outward from the perimeter of electrical assembly 160. Underfill material 170 should not be allowed to reach waveguide 114, as that event could cause defects. In this case, trench 152 acts as a barrier to impede or block excess underfill material 170 from reaching waveguide 114. Waveguide 114 should remain free from dust and contamination from underfill material 170. To achieve the protection for waveguide 114, the excess underfill material 170 flows into trench 152 and is blocked from reaching the waveguide. Underfill material 170 is shown as being impeded by trench 152 proximate to waveguide 114 as the underfill barrier. FIG. 4c shows excess underfill material 170 flowing into trench 152 and thus blocked from reaching waveguide 114. FIG. 4d is a top view of excess underfill material 170 flowing into trench 152 and thus blocked from reaching waveguide 114.

In FIG. 4e, an electrically conductive bump material is deposited over conductive layer 122 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 174. In one embodiment, bump 174 is formed over a UBM having a wetting layer, barrier layer, and adhesive layer. Bump 174 can also be compression bonded or thermocompression bonded to conductive layer 122. Bump 174 represents one type of interconnect structure that can be formed over conductive layer 122. The interconnect structure can also use bond wires, conductive paste, stud bump, micro bump, or other electrical interconnect.

The combination of interconnect substrate 120, electrical component 166, electrical assembly 160, and underfill material 170 constitute CPO 180. Underfill material 170 is shown as being impeded by trench 152 proximate to waveguide 114, i.e., the barrier to impede or block progression of the underfill material toward the waveguide, in CPO 180. The underfill barrier provided by trench 152 protects waveguide 114 from damage and defects potentially caused by the bleeding of underfill material 170. The underfill barrier increases process margin, capability, and yield, while reducing manufacturing costs.

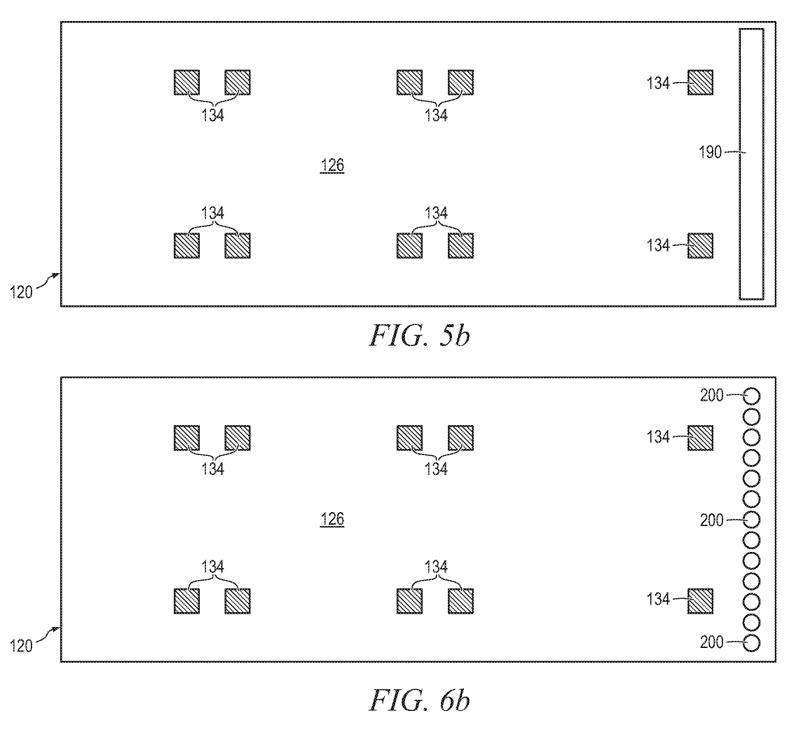

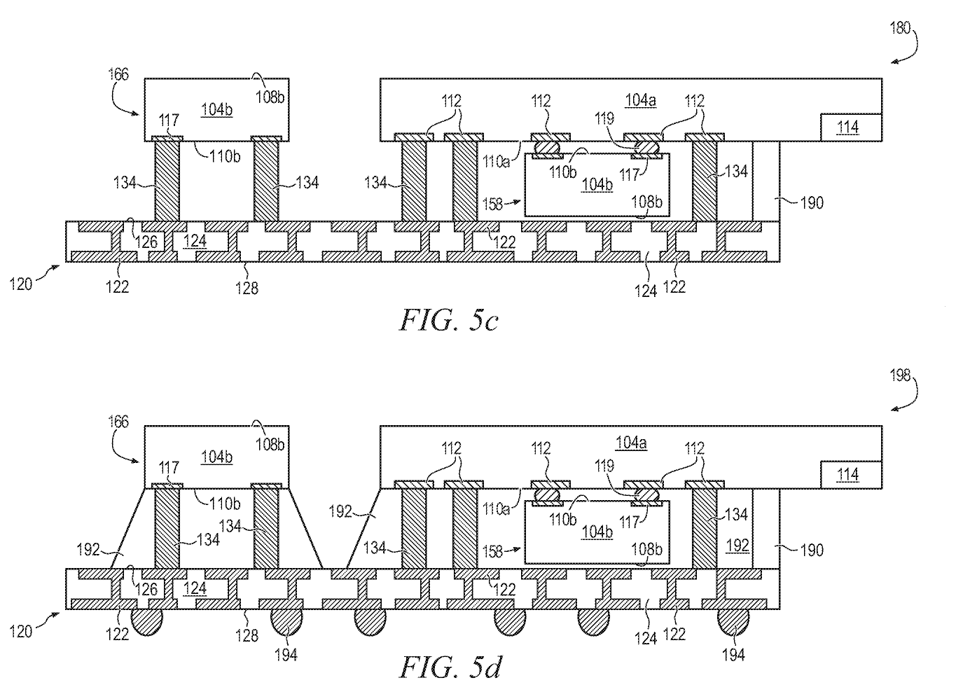

In another embodiment, continuing from FIG. 2e, solder resist dam 190 is formed over surface 126 of interconnect substrate 120, as shown in FIG. 5a. FIG. 5b is a top view of solder resist dam 190 formed over surface 126 of interconnect substrate 120 proximate to waveguide 114. In FIG. 5c, electrical assembly 160 and electrical component 166 are mounted to interconnect substrate 120, as described in FIGS. 4a-4b.

In FIG. 5d, an underfill material 192, such as epoxy resin, is deposited between electrical assembly 160 and interconnect substrate 120 and further between electrical component 166 and interconnect substrate 120. The dispensing of underfill material 192 can be difficult to control. Any excess underfill material 192 flows outward from the perimeter of electrical assembly 160. Underfill material 192 should not be allowed to reach waveguide 114, as that event could cause defects. In this case, solder resist dam 190 acts as a barrier to impede or block excess underfill material 192 from reaching waveguide 114. Waveguide 114 should remain free from dust and contamination from underfill material 192. To achieve the protection for waveguide 114, the excess underfill material 192 flowing up against solder resist dam 190 is blocked from reaching the waveguide. Underfill material 192 is shown as being impeded by solder resist dam 190 proximate to waveguide 114 as the underfill barrier.

The combination of interconnect substrate 120, electrical component 166, electrical assembly 160, and underfill material 192 constitute CPO 198. Underfill material 192 is shown as being impeded by solder resist dam 190 proximate to waveguide 114, i.e., the barrier to impede or block progression of the underfill material toward the waveguide, in CPO 198. The underfill barrier provided by solder resist dam 190 protects waveguide 114 from damage and defects potentially caused by the bleeding of underfill material 192. The underfill barrier increases process margin, capability, and yield, while reducing manufacturing costs.

An electrically conductive bump material is deposited over conductive layer 122 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 194. In one embodiment, bump 194 is formed over a UBM having a wetting layer, barrier layer, and adhesive layer. Bump 194 can also be compression bonded or thermocompression bonded to conductive layer 122. Bump 194 represents one type of interconnect structure that can be formed over conductive layer 122. The interconnect structure can also use bond wires, conductive paste, stud bump, micro bump, or other electrical interconnect. The combination of interconnect substrate 120, electrical component 166, electrical assembly 160, and underfill material 192 constitute CPO 198. Underfill material 192 is shown impeded by solder resist dam 190 proximate to waveguide 114 in CPO 198.

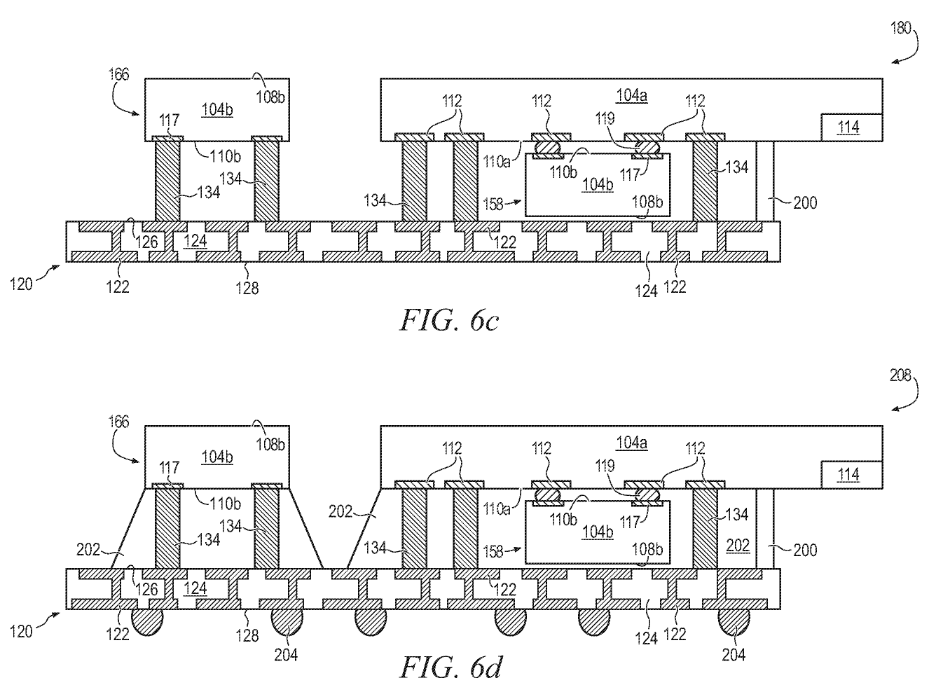

In another embodiment, continuing from FIG. 2e, posts 200 is formed over surface 126 of interconnect substrate 120, as shown in FIG. 6a. FIG. 6b is a top view of posts 200 formed over surface 126 of interconnect substrate 120 proximate to waveguide 114. Posts 200 can be metal or other rigid material. In FIG. 6c, electrical assembly 160 and electrical component 166 are mounted to interconnect substrate 120, as described in FIGS. 4a-4b.

In FIG. 6d, an underfill material 202, such as epoxy resin, is deposited between electrical assembly 160 and interconnect substrate 120 and further between electrical component 166 and interconnect substrate 120. The dispensing of underfill material 202 can be difficult to control. Any excess underfill material 202 flows outward from the perimeter of electrical assembly 160. Underfill material 202 should not be allowed to reach waveguide 114, as that event could cause defects. In this case, posts 200 act as a barrier to impede or block excess underfill material 202 from reaching waveguide 114. Waveguide 114 should remain free from dust and contamination from underfill material 202. To achieve the protection for waveguide 114, the excess underfill material 202 flows up against posts 200 and is blocked from reaching the waveguide. Underfill material 202 is shown as being impeded by posts 200 proximate to waveguide 114 as the underfill barrier.

An electrically conductive bump material is deposited over conductive layer 122 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 204. In one embodiment, bump 204 is formed over a UBM having a wetting layer, barrier layer, and adhesive layer. Bump 204 can also be compression bonded or thermocompression bonded to conductive layer 122. Bump 204 represents one type of interconnect structure that can be formed over conductive layer 122. The interconnect structure can also use bond wires, conductive paste, stud bump, micro bump, or other electrical interconnect. The combination of interconnect substrate 120, electrical component 166, electrical assembly 160, and underfill material 202 constitute CPO 208. Underfill material 202 is shown impeded by posts 200 proximate to waveguide 114 in CPO 208.

The combination of interconnect substrate 120, electrical component 166, electrical assembly 160, and underfill material 202 constitute CPO 208. Underfill material 202 is shown as being impeded by posts 200 proximate to waveguide 114, i.e., the barrier to impede or block progression of the underfill material toward the waveguide, in CPO 208. The underfill barrier provided by posts 200 protects waveguide 114 from damage and defects potentially caused by the bleeding of underfill material 202. The underfill barrier increases process margin, capability, and yield, while reducing manufacturing costs.

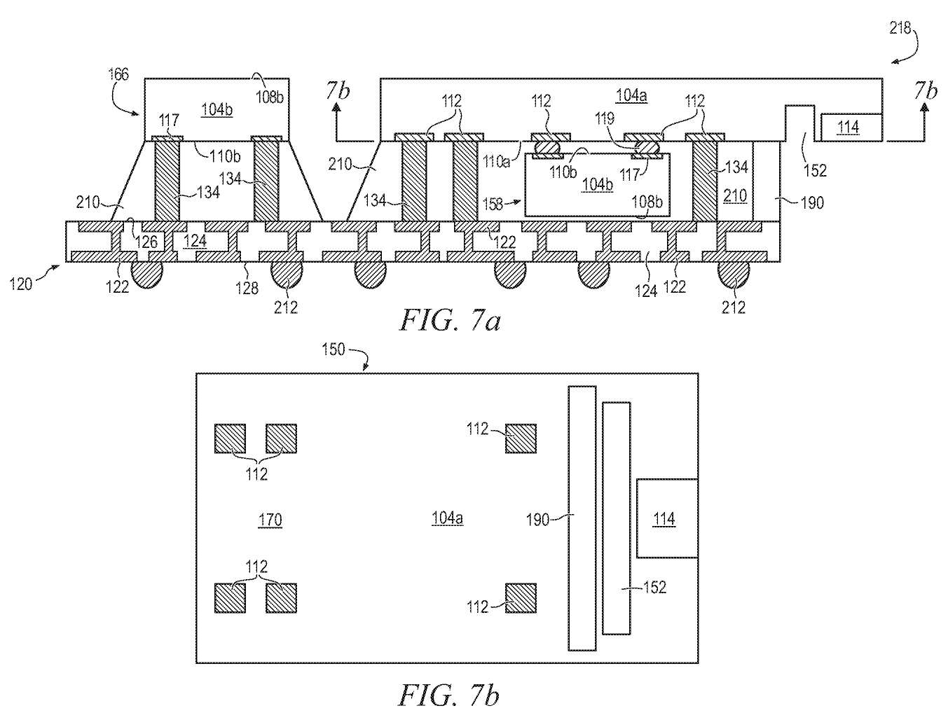

FIG. 7a shows an embodiment with a combination of solder resist dam 190 from FIGS. 5a-5d and trench 152 from FIGS. 4a-4e. FIG. 7b is a top view of solder resist dam 190 formed over surface 126 of interconnect substrate 120 and trench 152 formed on the surface of electrical component 150 proximate to waveguide 114. An underfill material 210, such as epoxy resin, is deposited between electrical assembly 160 and interconnect substrate 120 and further between electrical component 166 and interconnect substrate 120. The dispensing of underfill material 210 can be difficult to control. Any excess underfill material 210 flows outward from the perimeter of electrical assembly 160. Underfill material 210 should not be allowed to reach waveguide 114, as that event could cause defects. In this case, the combination of solder resist dam 190 and trench 152 acts as barriers to impede or block excess underfill material 210 from reaching waveguide 114. Waveguide 114 should remain free from dust and contamination from underfill material 210. To achieve the protection for waveguide 114, the excess underfill material 210 flows up against solder resist dam 190 and into trench 152 and is blocked from reaching the waveguide. Underfill material 210 is shown as being impeded by posts 200 and trench 152 proximate to waveguide 114, i.e., the underfill barrier.

An electrically conductive bump material is deposited over conductive layer 122 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 212. In one embodiment, bump 212 is formed over a UBM having a wetting layer, barrier layer, and adhesive layer. Bump 212 can also be compression bonded or thermocompression bonded to conductive layer 122. Bump 212 represents one type of interconnect structure that can be formed over conductive layer 122. The interconnect structure can also use bond wires, conductive paste, stud bump, micro bump, or other electrical interconnect. The combination of interconnect substrate 120, electrical component 166, electrical assembly 160, and underfill material 210 constitute CPO 218. Underfill material 210 is shown impeded by a combination of solder resist dam 190 and trench 152 proximate to waveguide 114 in CPO 218.

The combination of interconnect substrate 120, electrical component 166, electrical assembly 160, and underfill material 210 constitute CPO 218. Underfill material 210 is shown as being impeded by a combination of solder resist dam 190 and trench 152 proximate to waveguide 114, i.e., the barrier to impede or block progression of the underfill material toward the waveguide, in CPO 218. The underfill barrier provided by solder resist dam 190 and trench 152 protects waveguide 114 from damage and defects potentially caused by the bleeding of underfill material 210. The underfill barrier increases process margin, capability, and yield, while reducing manufacturing costs.

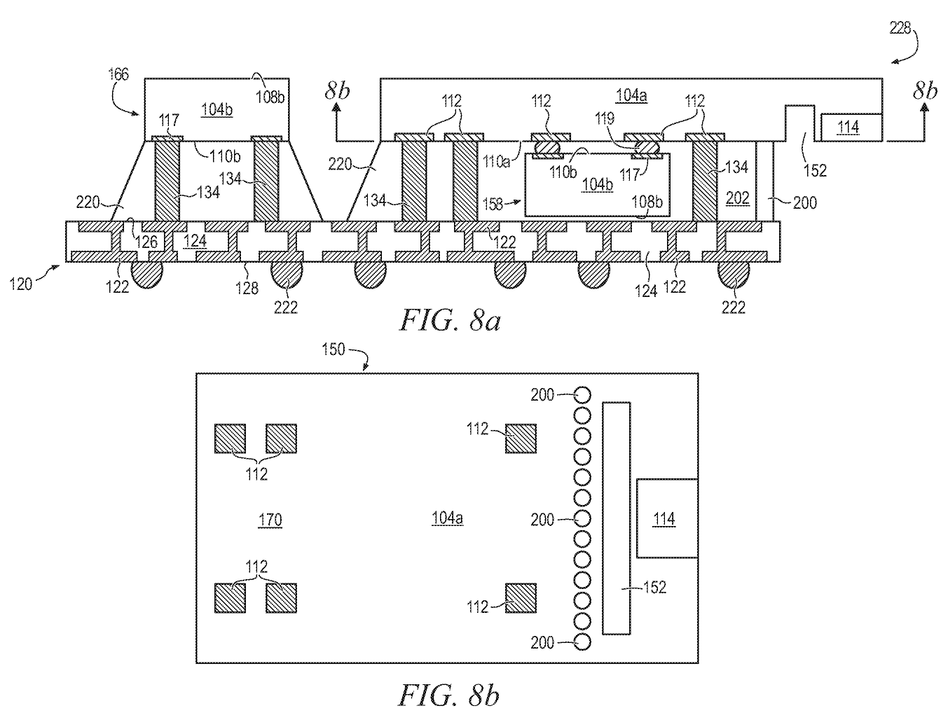

FIG. 8a shows an embodiment with a combination of posts 200 from FIGS. 6a-6d and trench 152 from FIGS. 4a-4e. FIG. 8b is a top view of posts 200 formed over surface 126 of interconnect substrate 120 and trench 152 formed on the surface of electrical component 150 proximate to waveguide 114. An underfill material 220, such as epoxy resin, is deposited between electrical assembly 160 and interconnect substrate 120 and further between electrical component 166 and interconnect substrate 120. The dispensing of underfill material 220 can be difficult to control. Any excess underfill material 220 flows outward from the perimeter of electrical assembly 160. Underfill material 220 should not be allowed to reach waveguide 114, as that event could cause defects. In this case, the combination of posts 200 and trench 152 acts as barriers to impede or block excess underfill material 220 from reaching waveguide 114. Waveguide 114 should remain free from dust and contamination from underfill material 220. To achieve the protection for waveguide 114, the excess underfill material 220 flows up against posts 200 and into trench 152 and is blocked from reaching the waveguide. Underfill material 220 is shown as being impeded by posts 200 and trench 152 proximate to waveguide 114, i.e., the underfill barrier.

An electrically conductive bump material is deposited over conductive layer 122 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 222. In one embodiment, bump 222 is formed over a UBM having a wetting layer, barrier layer, and adhesive layer. Bump 222 can also be compression bonded or thermocompression bonded to conductive layer 122. Bump 222 represents one type of interconnect structure that can be formed over conductive layer 122. The interconnect structure can also use bond wires, conductive paste, stud bump, micro bump, or other electrical interconnect. The combination of interconnect substrate 120, electrical component 166, electrical assembly 160, and underfill material 220 constitute CPO 228. Underfill material 220 is shown impeded by a combination of posts 200 and trench 152 proximate to waveguide 114 in CPO 228.

The combination of interconnect substrate 120, electrical component 166, electrical assembly 160, and underfill material 220 constitute CPO 228. Underfill material 220 is shown as being impeded by a combination of posts 200 and trench 152 proximate to waveguide 114, i.e., the barrier to impede or block progression of the underfill material toward the waveguide, in CPO 228. The underfill barrier provided by posts 200 and trench 152 protects waveguide 114 from damage and defects potentially caused by the bleeding of underfill material 220. The underfill barrier increases process margin, capability, and yield, while reducing manufacturing costs.

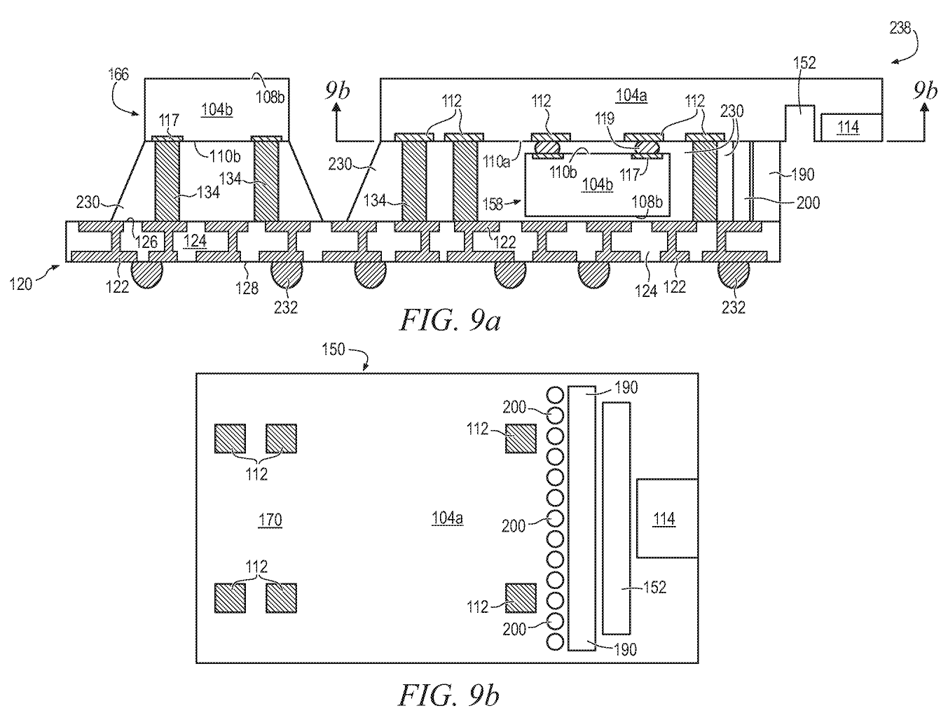

FIG. 9a shows an embodiment with a combination of posts 200 from FIGS. 6a-6d, solder resist dam 190 from FIGS. 5a-5d, and trench 152 from FIGS. 4a-4e. FIG. 9b is a top view of posts 200 and solder resist dam 190 formed over surface 126 of interconnect substrate 120 and trench 152 formed on the surface of electrical component 150 proximate to waveguide 114. An underfill material 230, such as epoxy resin, is deposited between electrical assembly 160 and interconnect substrate 120 and further between electrical component 166 and interconnect substrate 120. Underfill material 230 expands under electrical components 150 and 166 by a capillary effect. The dispensing of underfill material 230 can be difficult to control. Any excess underfill material 230 flows outward from the perimeter of electrical assembly 160. Underfill material 230 should not be allowed to reach waveguide 114, as that event could cause defects. In this case, the combination of posts 200, solder resist dam 190, and trench 152 acts as barriers to impede or block excess underfill material 230 from reaching waveguide 114. Waveguide 114 should remain free from dust and contamination from underfill material 230. To achieve the protection for waveguide 114, the excess underfill material 230 flows up against posts 200 and solder resist dam 190 and into trench 152 and is blocked from reaching the waveguide. Underfill material 230 is shown as being impeded by posts 200, solder resist dam 190, and trench 152 proximate to waveguide 114, i.e., the underfill barrier.

An electrically conductive bump material is deposited over conductive layer 122 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 232. In one embodiment, bump 232 is formed over a UBM having a wetting layer, barrier layer, and adhesive layer. Bump 232 can also be compression bonded or thermocompression bonded to conductive layer 122. Bump 232 represents one type of interconnect structure that can be formed over conductive layer 122. The interconnect structure can also use bond wires, conductive paste, stud bump, micro bump, or other electrical interconnect.

The combination of interconnect substrate 120, electrical component 166, electrical assembly 160, and underfill material 230 constitute CPO 238. Underfill material 230 is shown as being impeded by a combination of posts 200, solder resist dam 190, and trench 152 proximate to waveguide 114, i.e., the barrier to impede or block progression of the underfill material toward the waveguide, in CPO 238. The underfill barrier provided by posts 200, solder resist dam 190, and trench 152 protects waveguide 114 from damage and defects potentially caused by the bleeding of underfill material 230. The underfill barrier increases process margin, capability, and yield, while reducing manufacturing costs.

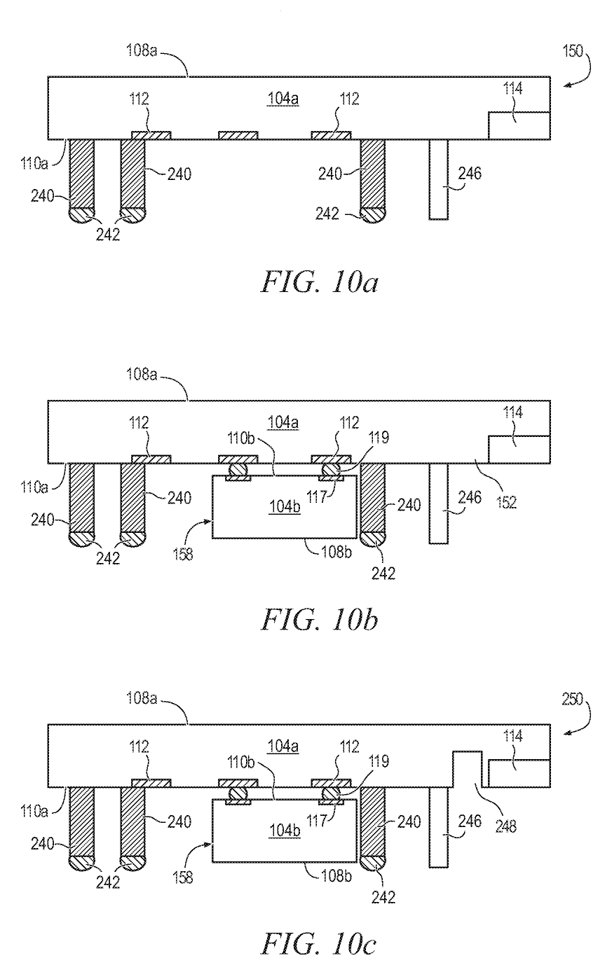

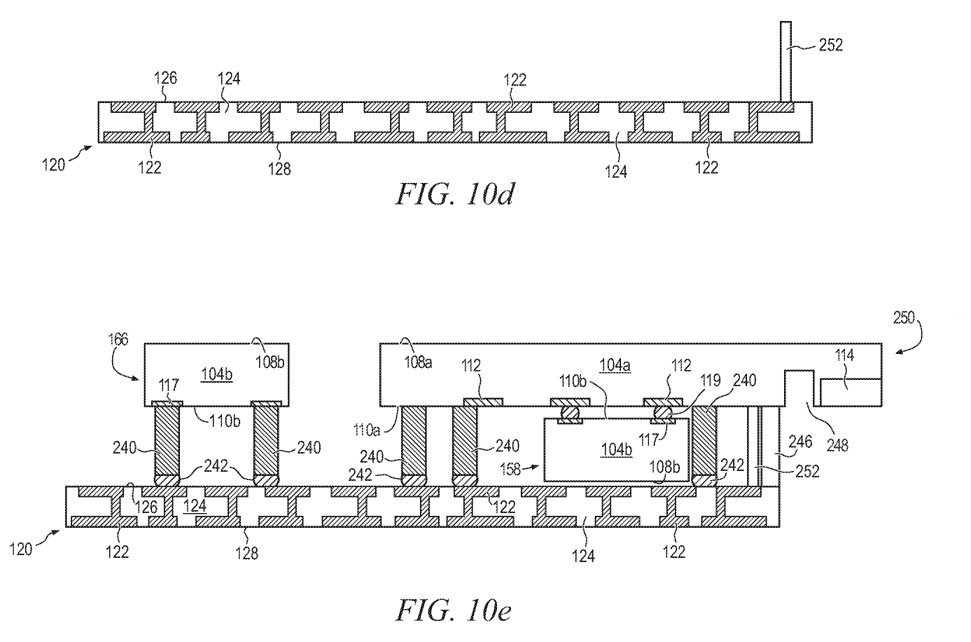

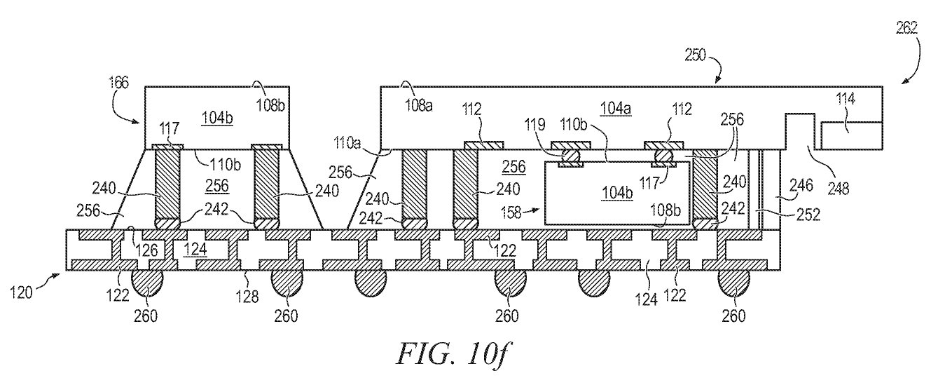

In another embodiment, continuing from FIG. 3a, conductive pillars 240 with bumps 242 are formed on conductive layer 112 of electrical component 150, as shown in FIG. 10a. Conductive pillars 240 can be formed similar to FIGS. 2b-2g. Solder resist dam 246 is formed over active surface 110, similar to FIGS. 5a-5b. Components having a similar function are assigned the same reference number.

In FIG. 10b, electrical component 158 is mounted to electrical component 150 with bumps 119 mechanically and electrically connected to conductive layer 112, similar to FIGS. 3f and 3g. In FIG. 10c, a trench or channel 248 is formed in a surface of electrical component 150 proximate to waveguide 114, similar to FIGS. 3b-3e. Electrical component 158 bonded to electrical component 150 with solder resist dam 246 and trench 248 constitutes electrical assembly 250.

In FIG. 10d, solder resist dam 252 is formed over surface 126 of interconnect substrate 120, similar to FIG. 5a. A top view of solder resist dam 246 and 252 would be similar to FIG. 5b. In FIG. 10e, electrical assembly 250 and electrical component 166 with conductive pillars 240 are mounted to interconnect substrate 120, similar to FIGS. 4a-4b. In FIG. 10f, an underfill material 256, such as epoxy resin, is deposited between electrical assembly 250 and interconnect substrate 120 and further between electrical component 166 and interconnect substrate 120. The dispensing of underfill material 256 can be difficult to control. Any excess underfill material 256 flows outward from the perimeter of electrical assembly 250. Underfill material 256 should not be allowed to reach waveguide 114, as that event could cause defects. In this case, the combination of solder resist dam 252, solder resist dam 246, and trench 248 acts as barriers to impede or block excess underfill material 256 from reaching waveguide 114. Waveguide 114 should remain free from dust and contamination from underfill material 256. To achieve the protection for waveguide 114, the excess underfill material 256 flows up against solder resist dam 252 and solder resist dam 246 and into trench 248 and is blocked from reaching the waveguide. Underfill material 256 is shown as being impeded by solder resist dam 252, solder resist dam 246, and trench 248 proximate to waveguide 114, i.e., the underfill barrier.

An electrically conductive bump material is deposited over conductive layer 122 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 260. In one embodiment, bump 260 is formed over a UBM having a wetting layer, barrier layer, and adhesive layer. Bump 260 can also be compression bonded or thermocompression bonded to conductive layer 122. Bump 260 represents one type of interconnect structure that can be formed over conductive layer 122. The interconnect structure can also use bond wires, conductive paste, stud bump, micro bump, or other electrical interconnect.

The combination of interconnect substrate 120, electrical component 166, electrical assembly 250, and underfill material 256 constitute CPO 262. Underfill material 256 is shown as being impeded by a combination of solder resist dam 252, solder resist dam 246, and trench 248 proximate to waveguide 114, i.e., the barrier to impede or block progression of the underfill material toward the waveguide, in CPO 262. The underfill barrier provided by solder resist dam 252, solder resist dam 246, and trench 248 protects waveguide 114 from damage and defects potentially caused by the bleeding of underfill material 256. The underfill barrier increases process margin, capability, and yield, while reducing manufacturing costs.

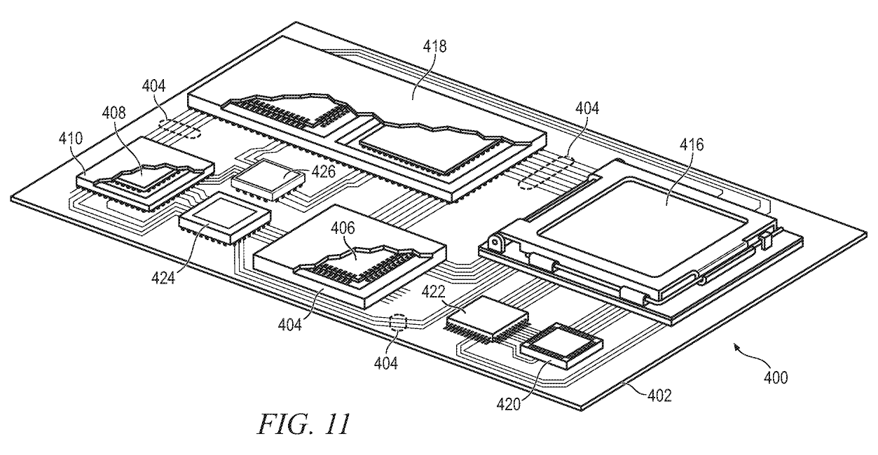

FIG. 11 illustrates electrical device 400 having a chip carrier substrate or PCB 402 with a plurality of semiconductor packages disposed on a surface of PCB 402, including CPO packages 180, 198, 208, 218, 228, 238, and 262. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 11, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB.

For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
an electrical component including a waveguide formed on the electrical component;
a barrier disposed proximate to the waveguide; and
an underfill material deposited under the electrical component, wherein the barrier impedes the underfill material from reaching the waveguide.

2. The semiconductor device of claim 1, wherein the barrier includes a trench.

3. The semiconductor device of claim 1, wherein the barrier includes a dam.

4. The semiconductor device of claim 1, wherein the barrier includes a post.

5. The semiconductor device of claim 1, further including an interconnect substrate, wherein the electrical component is disposed over the interconnect substrate.

6. The semiconductor device of claim 5, further including a conductive pillar formed between the interconnect substrate and the electrical component.

7. A semiconductor device, comprising:
an electrical component including an optical region;
a barrier disposed proximate to the optical region; and
an underfill material deposited under the electrical component, wherein the barrier impedes the underfill material from reaching the optical region.

8. The semiconductor device of claim 7, wherein the barrier includes a trench.

9. The semiconductor device of claim 7, wherein the barrier includes a dam.

10. The semiconductor device of claim 7, wherein the barrier includes a post.

11. The semiconductor device of claim 7, wherein the optical region includes a waveguide.

12. The semiconductor device of claim 7, further including an interconnect substrate, wherein the electrical component is disposed over the interconnect substrate.

13. The semiconductor device of claim 12, further including a conductive pillar formed between the interconnect substrate and the electrical component.

14. A method of making a semiconductor device, comprising:
providing an electrical component including a waveguide formed on the electrical component;
disposing a barrier proximate to the waveguide; and
depositing an underfill material under the electrical component, wherein the barrier impedes the underfill material from reaching the waveguide.

15. The method of claim 14, wherein the barrier includes a trench.

16. The method of claim 14, wherein the barrier includes a dam.

17. The method of claim 14, wherein the barrier includes a post.

18. The method of claim 14, further including providing an interconnect substrate, wherein the electrical component is disposed over the interconnect substrate.

19. The method of claim 18, further including forming a conductive pillar between the interconnect substrate and the electrical component.

20. A method of making a semiconductor device, comprising:
providing an electrical component including an optical region;
disposing a barrier proximate to the optical region; and
depositing an underfill material under the electrical component, wherein the barrier impedes the underfill material from reaching the optical region.

21. The method of claim 20, wherein the barrier includes a trench.

22. The method of claim 20, wherein the barrier includes a dam.

23. The method of claim 20, wherein the barrier includes a post.

24. The method of claim 20, wherein the optical region includes a waveguide.

25. The method of claim 20, further including providing an interconnect substrate, wherein the electrical component is disposed over the interconnect substrate.
